(19) United States
(12) Patent Application Publication
(10) Pub. No.: US 2009/0195328 A1
(43) Pub. Date: Aug. 6, 2009

(54) DELAY LINE, SIGNAL DELAY METHOD, AND TEST SIGNAL GENERATING APPARATUS

(75) Inventor: Kiyoto NAKAMURA, Tokyo (JP)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: ADVANTEST CORPORATION, Tokyo (JP)

(21) Appl. No.: 12/174,643

(22) Filed: Jul. 17, 2008

(30) Foreign Application Priority Data
Jul. 20, 2007 (JP) 2007190207

(51) Int. Cl. H03H 7/30

(52) U.S. Cl. 333/138

(57) ABSTRACT

Provided is a delay line that prevents reflection signals output from a test signal generator from being superimposed as noise. The delay line delays an electrical signal input into a signal line and outputs the thus delayed signal, and includes three or more passive elements that are provided on the signal line and delay the signal. Each section of the signal line between pairs of adjacent passive elements has a different electrical length. The reflection signals reflected by the passive elements are superimposed on each other at different phases. It is desirable that the reflection signals reflected by adjacent passive elements differ by 180 degrees.

### CROSS REFERENCE TO RELATED APPLICATION

The present application claims priority from a Japanese Patent Application No. 2007-190207 filed on Jul. 20, 2007, the contents of which are incorporated herein by reference.

### BACKGROUND

1. Technical Field

The present invention relates to a delay line, a signal delay method and a test signal generating apparatus. In particular, the present invention relates to a delay line, a signal delay method and a test signal generating apparatus for delaying a digital signal supplied to a device under test.

2. Background Art

A test waveform generator that supplies a test apparatus with a digital signal for testing the performance of a semiconductor is known, as in, for example, Japanese Patent Application Publication No. 2000-162288. This test waveform generator is provided with an RC circuit on a transmission line supplying the digital signal to the device under test. The test waveform generator can add an accent component to the waveform of the digital signal.

In this test waveform generator, the variable capacitance element of the RC circuit is grounded, which causes a portion of the digital signal passing through the RC circuit to be reflected by the RC circuit, resulting in overlap with the digital signal on the transmission line. This reflection superimposes an unnecessary noise component onto the digital signal.

### SUMMARY

Therefore, it is an object of an aspect of the innovations herein to provide a delay line, a signal delay method, and a test signal generating apparatus, which are capable of overcoming the above drawbacks accompanying the related art. The above and other objects can be achieved by combinations described in the independent claims. The dependent claims define further advantageous and exemplary combinations of the innovations herein.

According to a first aspect related to the innovations herein, one exemplary delay line may include a delay line that delays an electrical signal input into a signal line and outputs the thus delayed signal, including three or more passive elements that are provided on the signal line and delay the signal. Each section of the signal line between pairs of adjacent passive elements has a different electrical length.

According to a second aspect related to the innovations herein, one exemplary signal delay method may include a method for delaying a signal by selecting a set of three or more passive elements from among passive elements provided on a signal line to delay an electrical signal input into the signal line. The three or more passive elements are selected such that each section of the signal line between the selected passive elements has a different electrical length.

According to a third aspect related to the innovations herein, one exemplary test signal generating apparatus may include a signal generating circuit that generates a signal for testing a device under test and inputs the signal into a signal line, and a delay line that delays an electrical signal input into the signal delay line and outputs the resulting signal. The delay line includes three or more passive elements that are provided on the signal line and that delay the signal, and each section of the signal line between pairs of adjacent passive elements has a different electrical length.

The summary clause does not necessarily describe all necessary features of the embodiments of the present invention. The present invention may also be a sub-combination of the features described above. The above and other features and advantages of the present invention will become more apparent from the following description of the embodiments taken in conjunction with the accompanying drawings.

### BRIEF DESCRIPTION OF THE DRAWINGS

FIG. 1 is a block diagram showing a configuration of a test signal generator 10 according to an embodiment of the present invention.

FIG. 2 is an overhead view of the delay line 100.

FIG. 3 is a cross-sectional view taken from line A-A of FIG. 2 showing a state during which power is not supplied to the passive element 405.

FIG. 4 is a cross-sectional view taken from line A-A of FIG. 2 showing a state during which power is supplied to the passive element 405.

FIG. 5 shows a configuration of the delay line 100.

FIG. 6 shows a configuration of a delay line 101 as another embodiment of the delay line 100.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

Hereinafter, some embodiments of the present invention will be described. The embodiments do not limit the invention according to the claims, and all the combinations of the features described in the embodiments are not necessarily essential to means provided by aspects of the invention.

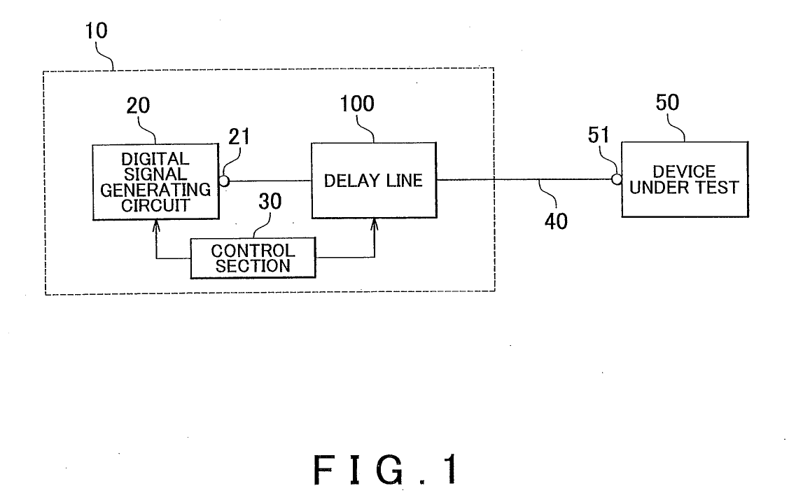

FIG. 1 is a block diagram showing a configuration of a test signal generator 10 according to an embodiment of the present invention. The test signal generator 10 provides a digital signal for testing a device under test 50. The test signal generator 10 is provided with a digital signal generating circuit 20, a control section 30, a signal line 40, and a delay line 100.

The signal line 40 electrically connects an output terminal 21 of the digital signal generating circuit 20 to an input terminal 51 of the device under test 50. The delay line 100 is provided on the signal line 40. The control section 30 is electrically connected to the digital signal generating circuit 20, and is also electrically connected to passive elements 205, 305, 405, 505, 605 of the delay line 100 via power supply lines 251, 256, 351, 356, 451, 456, 551, 556, 651, 656, described hereinafter. The digital signal generating circuit 20 generates the digital signal for testing the device under test 50 according to a command from the control section 30, and the test signal generator 10 outputs this digital signal to the device under test 50 via the signal line 40.

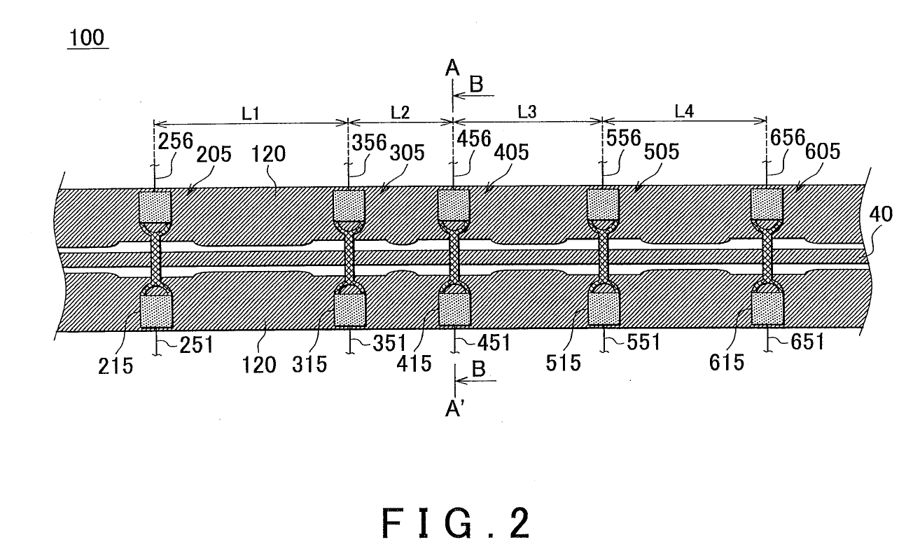

FIG. 2 is an overhead view of the delay line 100. The delay line 100 includes a substrate 110 having the signal line 40 patterned thereon, a ground 120 patterned on both sides of the signal line 40 with a space opened therebetween, and five passive elements 205, 305, 405, 505, 605 that straddle the signal line 40. Both ends of each passive element are fixed on the ground 120. The five passive elements 205, 305, 405, 505, 605 include flexible members 215, 315, 415, 515, 615, respectively. Each end of each passive element is connected to one end of a power supply line 251, 256, 351, 356, 451, 456, 551, 556, 651, 656. Each power supply line 251, 256, 351, 356, 451, 456, 551, 556, 651, 656 includes a line that provides a reference voltage and a line that provides a voltage corresponding to the supplied power.

As shown in FIG. 2, the five passive elements 205, 305, 405, 505, 605 are provided on the signal line 40 with a space opened between each passive element. The amount of space between each passive element is different. For example, the space between the passive element 205 and the passive element 305, shown by L1 in FIG. 2, is different than the space between the passive element 305 and the passive element 405, shown by L2. Each space between pairs of adjacent passive elements is different, as shown by L1 to L4. These spaces L1 to L4 may be randomly different, or may be sequentially larger in order from L1 to L4. Since the impedance of each unit length of the signal line is substantially equal in the present embodiment, the impedance between each pair of adjacent passive elements 205, 305, 405, 505, 605 differs according to the corresponding interval L1 to L4. Accordingly, the electrical length between each pair of adjacent passive elements 205, 305, 405, 505, 605 is different.

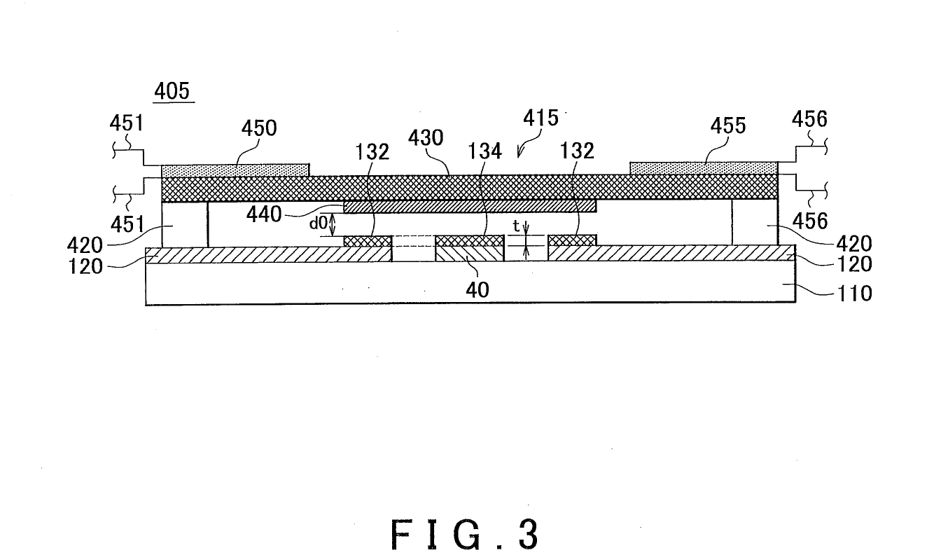

FIG. 3 is a cross-sectional view taken from line A-A and viewed from a direction B of FIG. 2. FIG. 3 shows a state during which power is not supplied to the passive element 405. The flexible member 415 of the passive element 405 includes supports 420 shaped as pillars and fixed on the ground 120 at both ends of the signal line 40, and an arm 430 that has both ends fixed on the supports 420. The arm 430 spans across the signal line 40 a certain distance above the signal line 40 and the ground 120.

The arm 430 is a flat plate having top and bottom surfaces that are substantially parallel to the top surfaces of the signal line 40 and the ground 120. The width of the top surface of the arm 430 is greater at both ends than in the center, and piezoelectric actuators 450, 455 are formed as sheets at both ends of the top surface. A movable electrode 440 having a uniform thickness is formed at the center of the bottom surface of the arm 430. Dielectric bodies 132, 134 are patterned on portions of the signal line 40 and the ground 120 facing the movable electrode 440. In the present embodiment, the dielectric bodies 132, 134 both have a thickness t, and the space between the dielectric bodies 132, 134 and the movable electrode 440 is d₀, as shown in FIG. 3.

As an example, the atmospheric permittivity is set to be ∈₀, the permittivity of the dielectric body 134 and the dielectric body 132 is set to be ∈₁, the respective areas of the dielectric body 134 and the dielectric body 132 are set to be S₀ and S₁, and the flexible member 415 is provided between the signal line 40 and the ground 120. Here, the surface area of the dielectric body 132 refers to the total area of the dielectric body 132 formed on the ground 120 on both sides of the signal line 40. Under these conditions, a coupling capacitance is achieved that can be expressed by ∈₀∈₁S₀S₁/{(∈₁d₀+∈₀t)S₁+(∈₁d₀+∈₀t)S₀}.

The surface of the piezoelectric actuator 450 contacting the arm 430 (referred to hereinafter as the “contact surface”) and the exposed surface of the piezoelectric actuator 450 are each connected to one of the two lines of the power supply line 451. In the same way, the surface of the piezoelectric actuator 455 contacting the arm 430 and the exposed surface of the piezoelectric actuator 455 are each connected to one of the two lines of the power supply line 456.

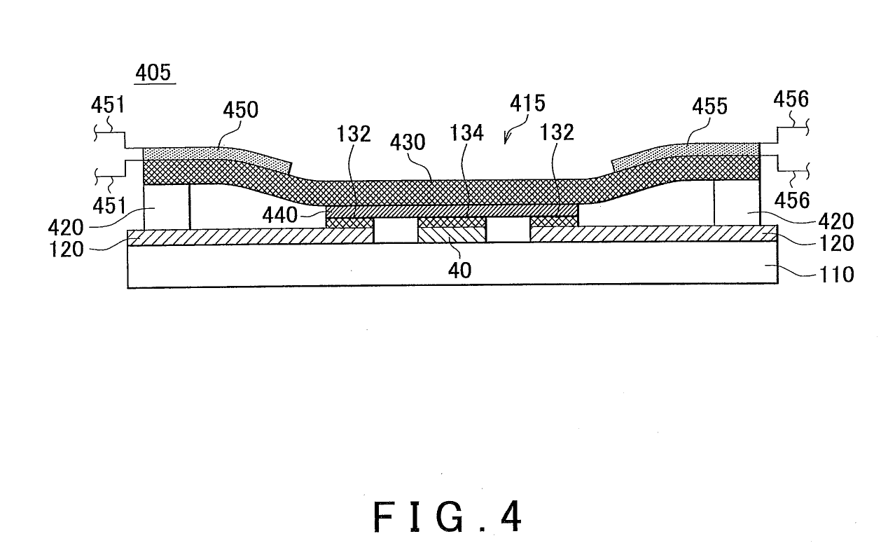

FIG. 4 is a cross-sectional view taken from line A-A and viewed from a direction B of FIG. 2. FIG. 4 shows a state during which power is supplied to the passive element 405. When power is supplied to the piezoelectric actuators 450, 455 on the flexible member 415 of the passive element 405 via the power supply lines 451, 456, as shown in FIG. 4, the piezoelectric actuators 450, 455 each bend in response to the voltage difference between the contact surface and the exposed surface. At this time, the arm 430 contacting the piezoelectric actuators 450, 455 bends along with the piezoelectric actuators 450, 455 so that the movable electrode 440 on the bottom surface of the arm 430 contacts the dielectric bodies 132, 134 at a position near the signal line 40 and the ground 120. The coupling capacitance between the signal line 40 and the ground 120 increases to an amount expressed by ∈₀∈₁S₀S₁/(∈₀tS₁+∈₀tS₀). The coupling capacitance can be increased further by using material for the dielectric bodies 132, 134 that has a higher permittivity, for example.

In this way, the passive element 405 supplies power to the piezoelectric actuators 450, 455 on the flexible member 415 to bend the piezoelectric actuators 450, 455. By bending the piezoelectric actuators 450, 455, the movable electrode 440 is brought near the signal line 40 and the ground 120, thereby increasing the coupling capacitance between the signal line 40 and the ground 120. The above describes an example focusing on the passive element 405, but passive elements 205, 305, 505, 605 provided on the signal line 40 have the same configuration and can increase the coupling capacitance between the signal line 40 and the ground 120 in the same way as the passive element 405.

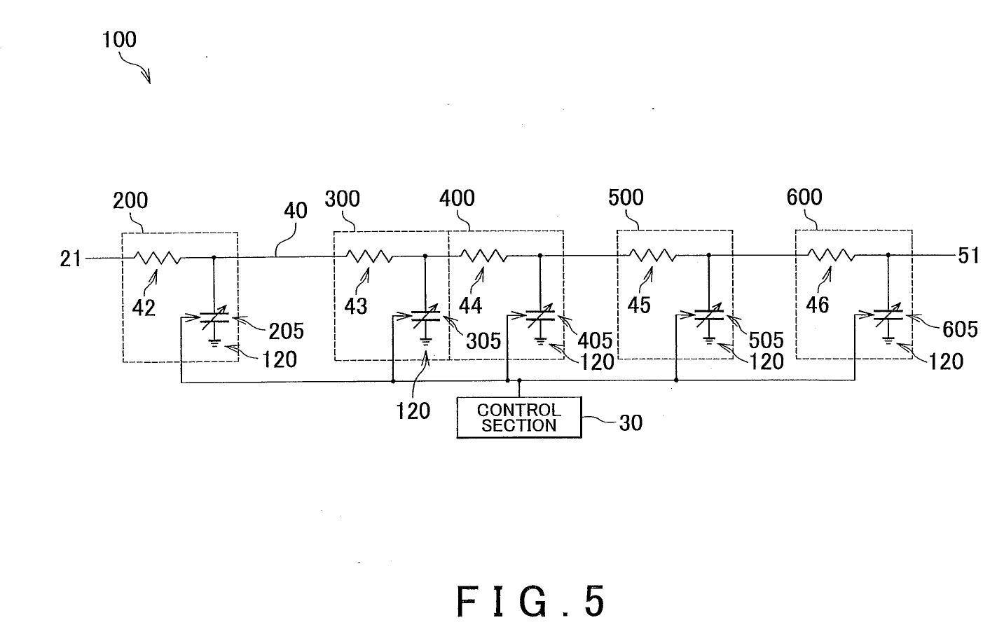

FIG. 5 shows a configuration of the delay line 100. Each of the five passive elements 205, 305, 405, 505, 605 provided on the signal line 40 of the delay line 100 forms one of a plurality of RC circuits 200, 300, 400, 500, 600 between each resistor 42, 43, 44, 45, 46 on the signal line 40. Accordingly, when a signal having a pulse waveform is transmitted on the signal line 40 of the delay line 100, for example, a delay is caused in the signal by supplying power to each flexible member 215, 315, 415, 515, 615 of each passive element 205, 305, 405, 505, 605 according to a prescribed timing from the control section 30. The amount of the delay in the present embodiment is approximately 1 psec for each passive element 205, 305, 405, 505, 605.

The amount of the delay in the signal caused by each passive element 205, 305, 405, 505, 605 depends on (i) the resistance of the corresponding resistor 42, 43, 44, 45, 46 and (ii) the amount of coupling capacitance of each flexible member 215, 315, 415, 515, 615 in the RC circuit 200, 300, 400, 500, 600 that include the passive elements 205, 305, 405, 505, 605, while power is being supplied to the flexible member 215, 315, 415, 515, 615. Accordingly, the amount of delay in the signal can be increased by increasing the coupling capacitance. The coupling capacitances of the passive elements 205, 305, 405, 505, 605 may all be equal or may each be different. In both cases, the control section 30 selects prescribed passive elements from among the five passive elements 205, 305, 405, 505, 605 to be supplied with power, based on the amount that the signal is to be delayed. By supplying power to the selected passive elements, the signal can be delayed by several different amounts.

Since each impedance is different between adjacent pairs of passive elements 205, 305, 405, 505, 605 in the delay line 100, as described above, the electrical length between each pair of adjacent passive elements 205, 305, 405, 505, 605 is also different. Accordingly, if the control section 30 selects three or more of the five passive elements 205, 305, 405, 505, 605 to supply power to, reflection signals, resulting from the signal transmitted on the signal line 40 being reflected by each of the selected passive elements, are superimposed on each other in the signal line 40 at different phases. Accordingly, the reflection signals weaken each other, and are therefore less likely to superimpose noise on the frequency components of the signal.

The five passive elements 205, 305, 405, 505, 605 are desirably provided on the signal line 40 of the delay line 100 in repetition, as shown in FIG. 2. A greater number of RC circuits can be formed on the signal line 40 using this configuration, since the control section 30 can selectively supply power to five or more passive elements. Accordingly, it is more likely that the reflection signals, resulting from the signal transmitted on the signal line 40 being reflected by the selected passive elements, will be superimposed on each other at different phases in the signal line 40. Therefore, the reflection signals are more likely to weaken each other. For this reason, it is desirable to have a larger number of passive elements on the signal line 40.

The flexible members 215, 315, 415, 515, 615 of the passive elements 205, 305, 405, 505, 605 are described above using the flexible member 415 as an example, but the present invention is not limited to a configuration in which the movable electrode 440 of the flexible member 415 is brought near to the signal line 40 and the ground 120 at both sides. For example, the movable electrode 440 of the flexible member 415 is fixed to one of the signal line 40 and the ground 120 to achieve contacting conduction therewith, and brought near the other to increase the coupling capacitance.

The passive elements 205, 305, 405, 505, 605 provided on the delay line 100 are substantially identical to capacitors when provided with power by the control section 30. In this way, the delay line 100 can delay the signal transmitted on the signal line 40 using the RC circuits 200, 300, 400, 500, 600 made up of the capacitors and resistors. On the other hand, if the delay line 100 uses active elements such as transistors, the waveform of the signal transmitted on the signal line 40 might be undesirably changed. But since the delay line 100 of the present embodiment uses passive elements, the delay line 100 can delay the signal transmitted on the signal line without altering the waveform of the signal.

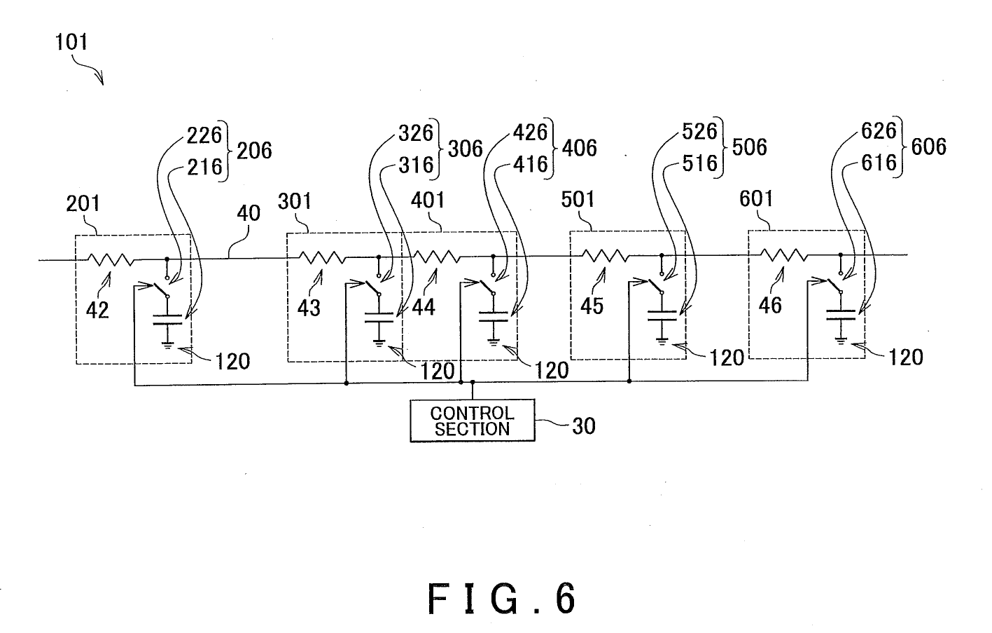

FIG. 6 shows a configuration of a delay line 101 as another embodiment of the delay line 100. In FIG. 6, configurations of the delay line 101 identical to those of the delay line 100 are given the same reference numerals, and descriptions thereof are omitted. The delay line 101 includes five passive elements 206, 306, 406, 506, 606 connected to the signal line 40. The five passive elements 206, 306, 406, 506, 606 respectively include (i) capacitors 216, 316, 416, 516, 616 connected between the signal line 40 and the ground 120 and (ii) switches 226, 326, 426, 526, 626 that electrically connect or disconnect the capacitors 216, 316, 416, 516, 616 to/from the signal line 40.

The control section 30 is electrically connected to the switches 226, 326, 426, 526, 626 and can independently connect or disconnect each of these switches. When the control section 30 connects the switches 226, 326, 426, 526, 626 so that the signal line 40 and the ground 120 are electrically connected via each capacitor 216, 316, 416, 516, 616, each of the five passive elements 206, 306, 406, 506, 606 forms the respective RC circuit 201, 301, 401, 501, 601 between each pair of the resistors 42, 43, 44, 45, 46. Accordingly, when the signal having a pulse waveform, for example, is transmitted on the signal line 40 of the delay line 101, the control section 30 can delay the signal by selecting prescribed switches with a specified timing from among the switches 226, 326, 426, 526, 626 of the passive elements 206, 306, 406, 506, 606.

The amount of the delay caused in the signal by each passive element 206, 306, 406, 506, 606 depends on the resistance of the corresponding resistor 42, 43, 44, 45, 46 and the capacitance of the corresponding capacitor 216, 316, 416, 516, 616 in the RC circuit 201, 301, 401, 501, 601 that includes the passive element 206, 306, 406, 506, 606. Accordingly, the delay amount in the signal caused by each passive element 206, 306, 406, 506, 606 can be increased by increasing the capacitance of the capacitors 216, 316, 416, 516, 616, for example.

The capacitances of the capacitors 216, 316, 416, 516, 616 may all be equal, or may each be different. In both cases, the signal can be delayed by various amounts since the control section 30 selects the prescribed passive elements from among the five passive elements 206, 306, 406, 506, 606 according to the desired delay amounts of the signal, and connects the corresponding switches.

The five passive elements 206, 306, 406, 506, 606 of the delay line 101 are provided on the signal line 40 with spaces between each passive element, and these spaces may each be different, in the same manner as the five passive elements 205, 305, 405, 505, 605 of the delay line 100. Therefore, if the control section 30 selects three or more passive elements from among the five passive elements 206, 306, 406, 506, 606 and connects the corresponding switches, the reflection signals, resulting from the selected passive elements reflecting the signal transmitted on the signal line 40, are superimposed on each other at different phases in the signal line 40. Accordingly, the reflection signals weaken each other, and are therefore less likely to superimpose noise on the frequency components of the signal.

The five passive elements 206, 306, 406, 506, 606 of the delay line 101 may be provided on the signal line 40 at uniform intervals. In this case, the control section 30 selects three or more passive elements from among the five passive elements 206, 306, 406, 506, 606 such that each space between pairs of the selected passive elements is different. The control section 30 then connects the switches corresponding to the selected passive elements, so that the reflection signals, resulting from the selected passive elements reflecting the signal transmitted on the signal line 40, are superimposed on each other at different phases. Accordingly, the reflection signals weaken each other, and are therefore less likely to superimpose noise on the frequency components of the signal.

The passive elements 206, 306, 406, 506, 606 of the delay line 101 include the switches 226, 326, 426, 526, 626 that can independently connect or disconnect the capacitors 216, 316, 416, 516, 616, respectively. With this configuration, the switches 226, 326, 426, 526, 626 of the passive elements 206, 306, 406, 506, 606 may be provided at different locations in the delay line 101, thereby increasing the amount of freedom when designing the test signal generator 10. Transistors, piezoelectric switches, or MEMS switches may be used as the switches 226, 326, 426, 526, 626.

The passive elements 206, 306, 406, 506, 606 of the delay line 101 are provided with capacitors 216, 316, 416, 516, 616, as described above. Therefore, the delay line 101 can delay the signal transmitted on the signal line 40 using the RC circuits 201, 301, 401, 501, 601, which are made up of the capacitors 216, 316, 416, 516, 616 and the resistors 42, 43, 44, 45, 46. On the other hand, if active elements such as transistors are used in the delay line 101, the waveform of the signal transmitted on the signal line 40 might be undesirably changed. Since the delay line 101 uses passive elements, the delay line 101 can delay the signal transmitted on the signal line 40 without changing the waveform of the signal. In the delay line 101, inductive elements such as coils may be provided on the signal line 40 at the positions of the resistors 42, 43, 44, 45, 46. With this configuration, the amount of delay in the signal caused by LC circuits formed of the inductive elements and the capacitors 216, 316, 416, 516, 616 can be changed by changing the induction amount of the inductive elements.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

As made clear from the above, by using the delay line of the present invention in a signal generator, reflection signals output from a test signal generator are prevented from being superimposed as noise. If three or more passive elements are selected to delay the signal, the passive elements can be selected such that each space between adjacent passive elements is different. In this way, the reflection signals reflected by the selected passive elements are superimposed on each other at different phases, so that the reflection signals weaken each other. Accordingly, the strength of the reflection signals is decreased.

What is claimed is:

1. A delay line that delays an electrical signal input into a signal line and outputs the thus delayed signal, comprising:
three or more passive elements that are provided on the signal line and that delay the signal, wherein
each section of the signal line between pairs of adjacent passive elements has a different electrical length.

2. The delay line according to claim 1, wherein
each section of the signal line between pairs of adjacent passive elements has a different impedance.

3. The delay line according to claim 1, wherein
each passive element reflects the signal to create a reflection signal, such that the reflection signals are superimposed on each other at different phases to weaken each other.

4. The delay line according to claim 1, wherein
each passive element includes a flexible member that is brought near the signal line and a ground to increase a coupling capacitance between the signal line and the ground, so as to delay the signal.

5. The delay line according to claim 1, wherein
each passive element includes a flexible member that is connected to at least one of the signal line and a ground and is brought near the other to increase a coupling capacitance between the signal line and the ground, so as to delay the signal.

6. The delay line according to claim 1, wherein
each passive element includes a switch that determines whether the signal is delayed by the corresponding passive element.

7. The delay line according to claim 1, wherein each passive element includes:
a capacitor that is connected between the signal line and a ground; and
a switch that provides or cuts off an electrical connection between the capacitor and the signal line or between the capacitor and the ground.

8. A method for delaying a signal by selecting a set of three or more passive elements from among passive elements provided on a signal line to delay an electrical signal input into the signal line, wherein
the three or more passive elements are selected such that each section of the signal line between the selected passive elements has a different electrical length.

9. The method according to claim 8, wherein
the three or more passive elements are selected such that each section of the signal line between the selected passive elements has a different impedance.

10. A test signal generating apparatus, comprising:
a signal generating circuit that generates a signal for testing a device under test and inputs the signal into a signal line; and
a delay line that delays an electrical signal input into the signal delay line and outputs the resulting signal, wherein
the delay line includes three or more passive elements that are provided on the signal line and that delay the signal, and
each section of the signal line between pairs of adjacent passive elements has a different electrical length.
